(19) United States
(12) Patent Application Publication
(10) Pub. No.: US 2026/0018386 A1
(43) Pub. Date: Jan. 15, 2026

(54) PLASMA PROCESSING APPARATUS

(71) Applicant: Tokyo Electron Limited, Tokyo (JP)

(72) Inventors: Naoki SATO, Kurokawa-gun (JP); Norihiko AMIKURA, Kurokawa-gun (JP)

(21) Appl. No.: 19/332,613

(22) Filed: Sep. 18, 2025

Related U.S. Application Data
(63) Continuation of application No. PCT/JP2024/005996, filed on Feb. 20, 2024.

(30) Foreign Application Priority Data
Mar. 29, 2023 (JP) 2023-053992

(51) Int. Cl. H01J 37/32

(52) U.S. Cl. CPC H01J 37/32458; H01J 2237/2445

(57) ABSTRACT

A plasma processing apparatus includes an outer chamber including an outer side wall, in which the outer side wall includes a first outer transparent window, a substrate support disposed in the inner space of the outer chamber, a replaceable inner chamber disposed in the inner space of the outer chamber, in which the replaceable inner chamber includes an upper plate that extends in a horizontal direction above the substrate support, an annular bottom plate that extends outward from a side wall of the substrate support, and an inner side wall that extends in a vertical direction to connect an outer periphery of the upper plate to an outer periphery of the annular bottom plate, and the inner side wall includes a first inner transparent window disposed to face the first outer transparent window, and a measurement device configured to optically measure a state of the replaceable inner chamber.

### CROSS-REFERENCE TO RELATED APPLICATIONS

This application is a bypass continuation application of international application No. PCT/JP2024/005996 having an international filing date of Feb. 20, 2024 and designating the United States, the international application being based upon and claiming the benefit of priority from Japanese Patent Application No. 2023-053992, filed on Mar. 29, 2023, the entire contents of each of which are incorporated herein by reference.

### BACKGROUND

### Field

An exemplary embodiment of the present disclosure relates to a plasma processing apparatus.

### Description of Related Art

Japanese Patent Application Laid-Open No. 2022-66828 discloses a technique in which a second chamber is disposed in a first chamber and the second chamber is transportable to an outside of the first chamber in a plasma processing apparatus.

### SUMMARY

A plasma processing apparatus in an exemplary embodiment of the present disclosure includes an outer chamber including an outer side wall, the outer side wall defining at least an inner space, and the outer side wall including a first outer transparent window; a substrate support disposed in the inner space of the outer chamber and having a substrate support surface; a replaceable inner chamber disposed in the inner space of the outer chamber, in which the replaceable inner chamber includes an upper plate extending in a horizontal direction above the substrate support, an annular bottom plate extending outward from a side wall of the substrate support, and an inner side wall extending in a vertical direction to connect an outer periphery of the upper plate to an outer periphery of the annular bottom plate, a plasma processing space is defined by the substrate support, the upper plate, the annular bottom plate, and the inner side wall, and the inner side wall includes a first inner transparent window disposed to face the first outer transparent window; and a measurement device configured to optically measure a state of the replaceable inner chamber via the first outer transparent window and the first inner transparent window.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a partially enlarged view for describing a configuration example of a part of the plasma processing apparatus.

FIG. 4 is a diagram for describing an example of a configuration of a gate valve.

FIG. 5 is a diagram for describing an example of a configuration of the gate valve.

FIG. 6 is a flowchart showing an example of processing of confirming a state of an inner chamber.

FIG. 7 is a partially enlarged view for describing another configuration example of a part of the plasma processing apparatus.

FIG. 8 is a diagram for describing a configuration example of a plasma processing apparatus according to a second embodiment.

FIG. 9 is a diagram for describing another configuration example of the plasma processing apparatus according to the second embodiment.

FIG. 10 is a diagram for describing a configuration example of a plasma processing apparatus according to a third embodiment.

FIG. 11 is a diagram for describing another configuration example of the plasma processing apparatus according to the third embodiment.

### DETAILED DESCRIPTION

Hereinafter, each embodiment according to the present disclosure will be described.

In an exemplary embodiment, a plasma processing apparatus is provided, the plasma processing apparatus including an outer chamber including an outer side wall, the outer side wall defining at least an inner space, and the outer side wall including a first outer transparent window; a substrate support disposed in the inner space of the outer chamber and having a substrate support surface; a replaceable inner chamber disposed in the inner space of the outer chamber, in which the replaceable inner chamber includes an upper plate extending in a horizontal direction above the substrate support, an annular bottom plate extending outward from a side wall of the substrate support, and an inner side wall extending in a vertical direction to connect an outer periphery of the upper plate to an outer periphery of the annular bottom plate, a plasma processing space is defined by the substrate support, the upper plate, the annular bottom plate, and the inner side wall, and the inner side wall includes a first inner transparent window disposed to face the first outer transparent window; and a measurement device configured to optically measure a state of the replaceable inner chamber via the first outer transparent window and the first inner transparent window.

In one exemplary embodiment, the outer side wall has an opening portion, the outer chamber includes a gate valve configured to open and close the opening portion, and the gate valve includes the first outer transparent window.

In one exemplary embodiment, the outer side wall includes a reflection mirror disposed on an opposite side of the first outer transparent window, the inner side wall includes a second inner transparent window that faces the reflection mirror and is disposed on an opposite side of the first inner transparent window, the measurement device includes a light source disposed in a vicinity of the first outer transparent window, and a detector disposed in the vicinity of the first outer transparent window, and the measurement device is configured to optically measure the state of the replaceable inner chamber via the first outer transparent window, the first inner transparent window, the second inner transparent window, and the reflection mirror.

In one exemplary embodiment, the outer side wall has a first opening portion and a second opening portion located on an opposite side of the first opening portion, the outer chamber includes a first gate valve configured to open and close the first opening portion, and a second gate valve configured to open and close the second opening portion, the first gate valve includes the first outer transparent window, and the second gate valve includes the reflection mirror.

In one exemplary embodiment, the outer side wall includes a second outer transparent window disposed on an opposite side of the first outer transparent window, the inner side wall includes a second inner transparent window that faces the second outer transparent window and is disposed on an opposite side of the first inner transparent window, the measurement device includes a light source disposed in a vicinity of the first outer transparent window, and a detector disposed in a vicinity of the second outer transparent window, and the measurement device is configured to optically measure the state of the replaceable inner chamber via the first outer transparent window, the first inner transparent window, the second inner transparent window, and the second outer transparent window.

In one exemplary embodiment, the outer side wall has a first opening portion and a second opening portion located on an opposite side of the first opening portion, the outer chamber includes a first gate valve configured to open and close the first opening portion, and a second gate valve configured to open and close the second opening portion, the first gate valve includes the first outer transparent window, and the second gate valve includes the second outer transparent window.

In one exemplary embodiment, a plasma processing apparatus is provided, the plasma processing apparatus including an outer chamber including an outer side wall, the outer side wall defining at least an inner space, and the outer side wall including a first outer transparent window; a substrate support disposed in the inner space of the outer chamber and having a substrate support surface; a replaceable inner chamber disposed in the inner space of the outer chamber, in which the replaceable inner chamber includes an upper plate extending in a horizontal direction above the substrate support, an annular bottom plate extending outward from a side wall of the substrate support, and an inner side wall extending in a vertical direction to connect an outer periphery of the upper plate to an outer periphery of the annular bottom plate, a plasma processing space is defined by the substrate support, the upper plate, the annular bottom plate, and the inner side wall, and the inner side wall includes at least one first through-hole facing the first outer transparent window; and a measurement device configured to optically measure a state of the replaceable inner chamber via the first outer transparent window and the at least one first through-hole.

In one exemplary embodiment, the outer side wall has an opening portion, the outer chamber includes a gate valve configured to open and close the opening portion, and the gate valve includes the first outer transparent window.

In one exemplary embodiment, the outer side wall includes a reflection mirror disposed on an opposite side of the first outer transparent window, the inner side wall includes at least one second through-hole that faces the reflection mirror and is located on an opposite side of the at least one first through-hole, the measurement device includes a light source disposed in a vicinity of the first outer transparent window, and a detector disposed in the vicinity of the first outer transparent window, and the measurement device is configured to optically measure the state of the replaceable inner chamber via the first outer transparent window, the at least one first through-hole, the at least one second through-hole, and the reflection mirror.

In one exemplary embodiment, the outer side wall has a first opening portion and a second opening portion located on an opposite side of the first opening portion, the outer chamber includes a first gate valve configured to open and close the first opening portion, and a second gate valve configured to open and close the second opening portion, the first gate valve includes the first outer transparent window, and the second gate valve includes the reflection mirror.

In one exemplary embodiment, the outer side wall includes a second outer transparent window disposed on an opposite side of the first outer transparent window, the inner side wall has at least one second through-hole that faces the second outer transparent window and is located on an opposite side of the at least one first through-hole, the measurement device includes a light source disposed in a vicinity of the first outer transparent window, and a detector disposed in a vicinity of the second outer transparent window, and the measurement device is configured to optically measure the state of the replaceable inner chamber via the first outer transparent window, the at least one first through-hole, the at least one second through-hole, and the second outer transparent window.

In one exemplary embodiment, the outer side wall has a first opening portion and a second opening portion located on an opposite side of the first opening portion, the outer chamber includes a first gate valve configured to open and close the first opening portion, and a second gate valve configured to open and close the second opening portion, the first gate valve includes the first outer transparent window, and the second gate valve includes the second outer transparent window.

In one exemplary embodiment, a plasma processing apparatus is provided, the plasma processing apparatus including an outer chamber including an outer side wall, the outer side wall defining at least an inner space, and the outer side wall including a first outer transparent window; a substrate support disposed in the inner space of the outer chamber and having a substrate support surface; and a replaceable inner chamber disposed in the inner space of the outer chamber, in which the replaceable inner chamber includes an upper plate extending in a horizontal direction above the substrate support, an annular bottom plate extending outward from a side wall of the substrate support, and an inner side wall extending in a vertical direction to connect an outer periphery of the upper plate to an outer periphery of the annular bottom plate, a plasma processing space is defined by the substrate support, the upper plate, the annular bottom plate, and the inner side wall, and the inner side wall includes a first inner transparent window disposed to face the first outer transparent window.

In one exemplary embodiment, the outer side wall has an opening portion, the outer chamber includes a gate valve configured to open and close the opening portion, and the gate valve includes the first outer transparent window.

In one exemplary embodiment, the outer side wall includes a reflection mirror disposed on an opposite side of the first outer transparent window, and the inner side wall includes a second inner transparent window that faces the reflection mirror and is disposed on an opposite side of the first inner transparent window.

In one exemplary embodiment, the outer side wall includes a second outer transparent window disposed on an opposite side of the first outer transparent window, the inner side wall includes a second inner transparent window that faces the second outer transparent window and is disposed on an opposite side of the first inner transparent window.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### First Embodiment

### <Example of Plasma Processing>

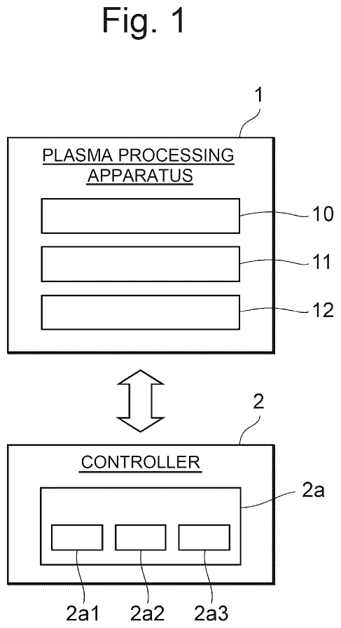

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 160 described later, and the gas exhaust port is connected to an exhaust apparatus 700 described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHZ. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

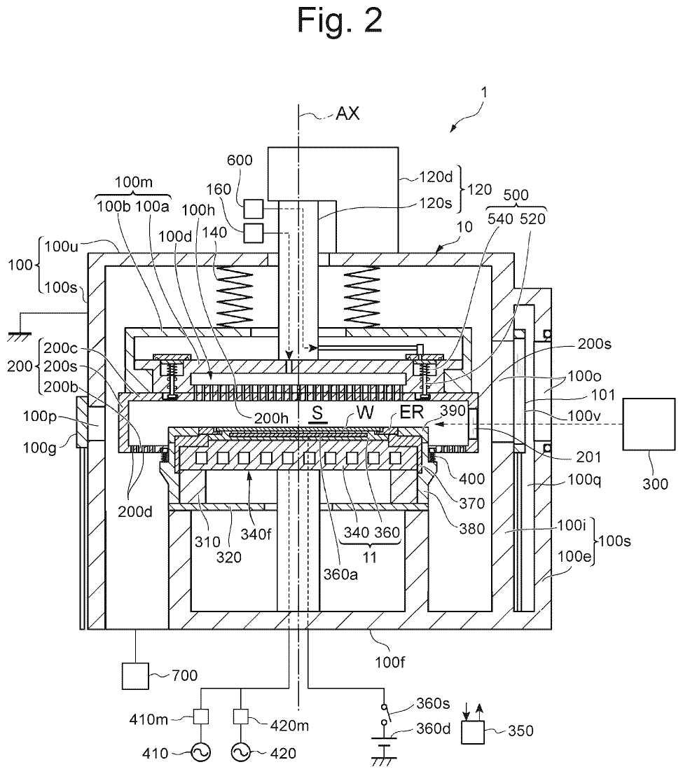

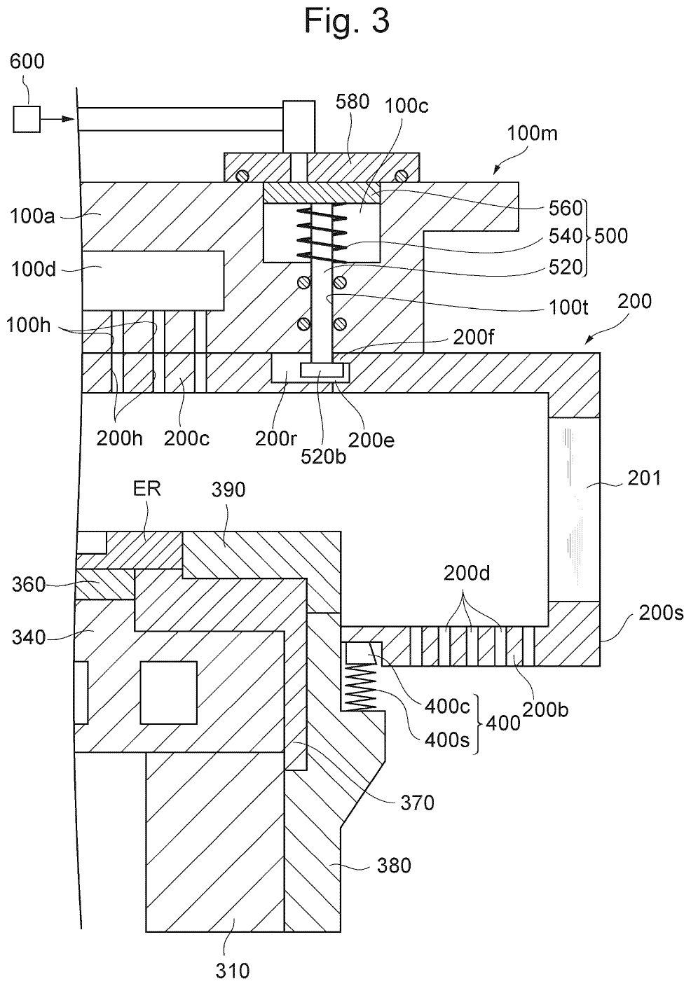

Hereinafter, a configuration example of a capacitively coupled plasma processing apparatus as an example of the plasma processing apparatus 1 will be described. FIG. 2 is a diagram for describing a configuration example of the capacitively coupled plasma processing apparatus 1. FIG. 3 is a partially enlarged view for describing a configuration example of a part of the plasma processing apparatus 1.

In an embodiment, as shown in FIG. 2, the plasma processing apparatus 1 includes an outer chamber 100, a replaceable inner chamber 200, a substrate support 11, and a measurement device 300. The outer chamber 100 and the inner chamber 200 are examples of the plasma processing chamber 10 described above.

In an embodiment, the outer chamber 100 may provide an inner space. The outer chamber 100 may be formed from a conductor made of a metal such as aluminum. The outer chamber 100 may be electrically grounded.

In an embodiment, the outer chamber 100 may include an outer side wall 100s, an upper portion 100u, and a bottom portion 100f. The outer side wall 100s may have a substantially cylindrical shape. A central axis of the outer side wall 100s extends in the vertical direction and may be shown as an axis AX in FIG. 2. The inner space of the outer chamber 100 may be defined by the outer side wall 100s, the upper portion 100u, and the bottom portion 100f. A second opening portion 100p may be disposed in the outer side wall 100s. The inner space of the outer chamber 100 may be connected to an inner space of a transport module installed outside the outer chamber 100 via the second opening portion 100p. The second opening portion 100p may be openable and closeable by a gate valve 100g. A substrate W may be transported via the second opening portion 100p between the inner space of the outer chamber 100 and the outside of the outer chamber 100.

In an embodiment, a first opening portion 1000 may be disposed in the outer side wall 100s. The first opening portion 1000 may be disposed to face the second opening portion 100p. The first opening portion 1000 may have a size through which the inner chamber 200 can pass. The inner space of the outer chamber 100 may be connected to the inner space of the transport module via the first opening portion 1000. The first opening portion 1000 may be openable and closeable by a gate valve 100v. The inner chamber 200 may be transported via the first opening portion 1000 between the inner space of the outer chamber 100 and the outside of the outer chamber 100.

In an embodiment, a part of the outer side wall 100s may have a double structure formed from an inner wall 100i and an outer wall 100e. A space 100q may be provided between the inner wall 100i and the outer wall 100e. The first opening portion 1000 may be formed in the inner wall 100i and the outer wall 100e. The gate valve 100v may be provided along the inner wall 100i in order to open and close the first opening portion 1000.

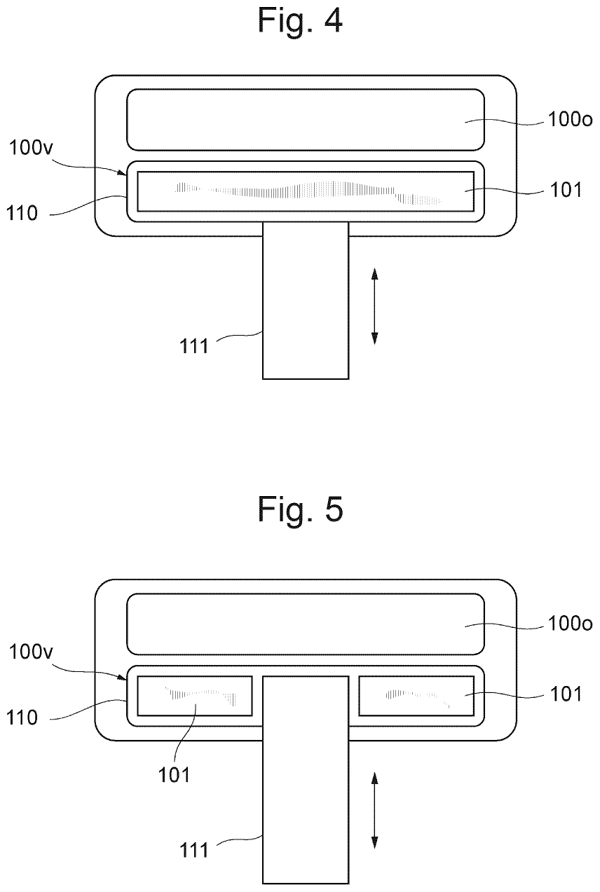

In an embodiment, the gate valve 100v may include a first outer transparent window 101. The first outer transparent window 101 may be made of glass, resin, or the like. As shown in FIG. 4, the gate valve 100v has a valve body 110 that can close the first opening portion 1000 and a support rod 111 that allows the valve body 110 to move up and down, and the first outer transparent window 101 may be disposed on the entire valve body 110. As shown in FIG. 5, the first outer transparent window 101 may be disposed on a part of the valve body 110. The first outer transparent window 101 may be divided into a plurality of parts.

In an embodiment, the upper portion 100u shown in FIG. 2 may have a disk shape having a plate surface facing vertically. The upper portion 100u may extend in a horizontal direction orthogonal to the axis AX from an upper end of the outer side wall 100s. An opening may be disposed in a region intersecting the axis AX in the upper portion 100u.

In an embodiment, the outer chamber 100 may further include a movable portion 100m. The movable portion 100m may or may not be a part of the outer chamber 100. The movable portion 100m may be disposed between the upper portion 100u of the outer chamber 100 and the inner chamber 200. The movable portion 100m may be configured to be movable upward and downward in the outer chamber 100.

In an embodiment, the plasma processing apparatus 1 may further include a lift mechanism 120. The lift mechanism 120 may move the movable portion 100m upward and downward. The lift mechanism 120 may include a driving apparatus 120d and a shaft 120s. The movable portion 100m may be fixed to the shaft 120s. The shaft 120s may extend upward from the movable portion 100m through the opening of the upper portion 100u. The driving apparatus 120d may be provided outside the outer chamber 100. The driving apparatus 120d may move the shaft 120s upward and downward. The driving apparatus 120d may include a motor. The movable portion 100m may move upward and downward by the movement of the shaft 120s upward and downward.

In an embodiment, the plasma processing apparatus 1 may further include a bellows 140 that is vertically expandable and contractible. The bellows 140 may be disposed between the movable portion 100m and the upper portion 100u. A lower end of the bellows 140 may be fixed to the movable portion 100m. An upper end of the bellows 140 may be fixed to the upper portion 100u. The bellows 140 may separate the inner space of the outer chamber 100 located outside the bellows 140 and the outer space of the outer chamber 100 communicating with the inside of the bellows 140.

In an embodiment, the movable portion 100m may include a first member 100a and a second member 100b. The first member 100a and the second member 100b may be fixed to each other. The first member 100a may have a substantially disk shape. The first member 100a may be formed from a conductor such as aluminum. The first member 100a may constitute an upper electrode in the plasma processing apparatus 1. The second member 100b may have a substantially cylindrical shape. The second member 100b may extend along an outer periphery of the first member 100a. The second member 100b may have an upper plate having a plate surface facing upward above the first member 100a. The lower end of the bellows 140 may be fixed to the upper plate of the second member 100b.

In an embodiment, the movable portion 100m may constitute a shower head together with an upper plate 200c of the inner chamber 200 described later. That is, the movable portion 100m may constitute a part of the shower head that supplies gas to a plasma processing space S described later. The movable portion 100m may have a gas diffusion chamber 100d and a plurality of gas holes 100h.

In an embodiment, the gas diffusion chamber 100d may be disposed in the first member 100a. The gas supply 160 may be connected to the gas diffusion chamber 100d. The gas supply 160 may be provided outside the outer chamber 100. The gas supply 160 may include one or more gas sources, one or more flow rate controllers, and one or more valves used in the plasma processing apparatus 1. Each of the one or more gas sources may be connected to the gas diffusion chamber 100d via a corresponding flow rate controller and a corresponding valve. The plurality of gas holes 100h may extend downward from the gas diffusion chamber 100d.

In an embodiment, the substrate support 11 may be disposed in the inner space of the outer chamber 100 and below the movable portion 100m. The substrate support 11 may have a substrate support surface. The substrate support 11 may be supported by a support 310 disposed below the substrate support 11. The support 310 may have a substantially cylindrical shape. The support 310 may be formed from an insulator such as quartz. The support 310 may extend upward from a bottom plate 320. The bottom plate 320 may be formed from a conductor made of a metal such as aluminum.

In an embodiment, the substrate support 11 may include a lower electrode 340 and an electrostatic chuck 360. The lower electrode 340 may have a substantially disk shape. The central axis of the lower electrode 340 may substantially coincide with the axis AX. The lower electrode 340 may be formed from a conductor such as aluminum. The lower electrode 340 may have a flow passage 340f therein. The flow passage 340f may extend in a spiral shape. The flow passage 340f may be connected to a chiller unit 350. The chiller unit 350 may be provided outside the outer chamber 100. The chiller unit 350 may supply a refrigerant to the flow passage 340f. The refrigerant supplied to the flow passage 340f may be returned to the chiller unit 350.

In an embodiment, the plasma processing apparatus 1 may further include a first RF power supply 410 and a second RF power supply 420. The first RF power supply 410 may be a power supply that generates a first RF power (RF signal). The first RF power may have a frequency suitable for forming a plasma. The frequency of the first RF power may be, for example, 27 MHz or more. The first RF power supply 410 may be electrically connected to the lower electrode 340 via a matcher 410m. A matching circuit may be provided in the matcher 410m to match an impedance on a load side (lower electrode 340 side) of the first RF power supply 410 with an output impedance of the first RF power supply 410. The first RF power supply 410 may be connected to the upper electrode via the matcher 410m instead of the lower electrode 340.

The second RF power supply 420 may be a power supply that generates a second RF power (RF signal). The second RF power may have a frequency suitable for drawing ions into the substrate W. The frequency of the second RF power may be, for example, 13.56 MHz or less. The second RF power supply 420 may be electrically connected to the lower electrode 340 via the matcher 420m. The matching circuit may be provided in the matcher 420m to match the impedance on the load side (lower electrode 340 side) of the second RF power supply 420 with the output impedance of the second RF power supply 420.

In an embodiment, the electrostatic chuck 360 may be provided on the lower electrode 340. The electrostatic chuck 360 may include a main body and an electrode 360a. The main body of the electrostatic chuck 360 may have a substantially disk shape. A central axis of the electrostatic chuck 360 may substantially coincide with the axis AX. The main body of the electrostatic chuck 360 may be formed from ceramic. The substrate W may be placed on an upper surface of the main body of the electrostatic chuck 360. The electrode 360a may be a film formed from a conductor. The electrode 360a may be provided in the main body of the electrostatic chuck 360. The electrode 360a may be connected to a direct current power supply 360d via a switch 360s. In an embodiment, when a voltage from the direct current power supply 360d is applied to the electrode 360a, an electrostatic attraction force may be generated between the electrostatic chuck 360 and the substrate W. The substrate W may be attracted to the electrostatic chuck 360 by the generated electrostatic attraction force and held by the electrostatic chuck 360. The plasma processing apparatus 1 may provide a gas line that supplies a heat transfer gas (for example, helium gas) to a gap between the electrostatic chuck 360 and a back surface of the substrate W.

The substrate support 11 may support an edge ring ER disposed thereon. The substrate W may be placed on the electrostatic chuck 360 in a region surrounded by the edge ring ER. The edge ring ER may be formed from, for example, silicon, quartz, or silicon carbide.

The substrate support 11 may further include an insulating portion 370. The insulating portion 370 may be formed from an insulator such as quartz. The insulating portion 370 may have a substantially cylindrical shape. The insulating portion 370 may extend along the outer periphery of the lower electrode 340 and the outer periphery of the electrostatic chuck 360.

The substrate support 11 may further include a conductor portion 380. The conductor portion 380 may be formed from a conductor such as aluminum. The conductor portion 380 may have a substantially cylindrical shape. The conductor portion 380 may be provided along the outer periphery of the substrate support 11. The conductor portion 380 may extend in an up-down direction along the outer periphery of the insulating portion 370. The conductor portion 380 may be connected to a ground. The conductor portion 380 may be grounded via the bottom plate 320, the bottom portion 100f of the outer chamber 100, and the like.

The substrate support 11 may further include a cover ring 390. The cover ring 390 may be formed from an insulator such as quartz. The cover ring 390 may have an annular shape. The cover ring 390 may be provided on the insulating portion 370 and the conductor portion 380 so as to be located outside a region where the edge ring ER is disposed.

The substrate support 11 may further include a contact 400. The contact 400 may be electrically connected to the conductor portion 380. The inner chamber 200 may abut against the contact 400 in a state of forming the plasma processing space S together with the substrate support 11. The contact 400 is disposed outside the cover ring 390 and may extend upward from the conductor portion 380.

The contact 400 may be configured to elastically come into contact with the inner chamber 200. As shown in FIG. 3, the contact 400 may have a spring 400s. The contact 400 may further have a contact portion 400c. The spring 400s and the contact portion 400c may have conductivity. A lower end of the spring 400s may be fixed to the conductor portion 380. The spring 400s may extend upward from the conductor portion 380. The contact portion 400c may be fixed to an upper end of the spring 400s. The contact portion 400c may be a portion that comes into contact with the inner chamber 200.

In an embodiment, as shown in FIG. 2, the inner chamber 200 may be disposed in the inner space of the outer chamber 100 to form the plasma processing space S together with the substrate support 11. The plasma processing space S may be a space in which plasma is formed and the substrate W is processed. The inner chamber 200 may be formed from a conductor.

In an embodiment, the inner chamber 200 may include the upper plate 200c, an annular bottom plate 200b, and an inner side wall 200s. The substrate support 11, the upper plate 200c, the annular bottom plate 200b, and the inner side wall 200s may define the plasma processing space S. The upper plate 200c may have a substantially disk shape. The upper plate 200c may extend in the horizontal direction above the plasma processing space S. An upper surface of the upper plate 200c may abut against a lower surface of the movable portion 100m. A plurality of gas holes 200h may be disposed in the upper plate 200c. The plurality of gas holes 200h may vertically penetrate the upper plate 200c and may be open toward the plasma processing space S. Each of the plurality of gas holes 200h may be connected to the plurality of gas holes 100h.

In an embodiment, the annular bottom plate 200b may have a substantially annular shape. The annular bottom plate 200b may extend in the horizontal direction outward from the side wall of the substrate support 11. The annular bottom plate 200b may abut against at least any one of the contact 400 and the conductor portion 380.

A plurality of through-holes 200d may be formed in the annular bottom plate 200b. The plasma processing apparatus 1 may further include the exhaust apparatus 700. The exhaust apparatus 700 may include a pressure adjuster such as an automatic pressure control valve and a decompression pump such as a turbo molecular pump. The exhaust apparatus 700 may be connected to the bottom portion 100f of the outer chamber 100 below the plurality of through-holes 200d.

In an embodiment, the inner side wall 200s may have a substantially cylindrical shape. The inner side wall 200s may extend in the circumferential direction on the side of the plasma processing space S. The inner side wall 200s may extend downward from an edge portion of the upper plate 200c and may be connected to an edge portion of the annular bottom plate 200b.

The inner side wall 200s may include a first inner transparent window 201. The first inner transparent window 201 may be disposed to face the first outer transparent window 101. The first inner transparent window 201 may be made of glass, resin, or the like.

In an embodiment, the inner chamber 200 may be removable from the outer chamber 100. As shown in FIGS. 2 and 3, the plasma processing apparatus 1 may further include a clamp 500 and a release mechanism 600. The clamp 500 may fix the inner chamber 200 to the outer chamber 100. The release mechanism 600 may release the fixation of the inner chamber 200 by the clamp 500.

In an embodiment, as shown in FIG. 3, the clamp 500 may fix the upper plate 200c of the inner chamber 200 to the movable portion 100m of the outer chamber 100 releasably. The clamp 500 may include a plurality of supports 520, a plurality of springs 540, and a plurality of plates 560. The number of the supports 520 of the clamp 500, the number of the springs 540, and the number of the plates 560 may each be one.

Each of the plurality of supports 520 may have a rod shape that is long vertically. Each of the plurality of supports 520 may have a lower end portion 520b that protrudes from the support main body in the horizontal direction. A plurality of cavities 100c formed on an upper surface of the first member 100a and a plurality of holes 100t that extend downward from the cavities 100c and vertically penetrate the first member 100a may be disposed in the movable portion 100m of the outer chamber 100. The cavity 100c may be closed by a lid body 580 provided on the upper surface of the first member 100a. Each of the plurality of supports 520 may be inserted into the cavity 100c and the hole 100t. A recess portion 200r may be disposed on the upper surface of the upper plate 200c of the inner chamber 200. The lower end portion 520b of the support 520 may be located at the recess portion 200r. The recess portion 200r may have an expansion portion (step portion) 200e that expands in the horizontal direction, and a locking portion 200f may be formed in the recess portion 200r by the expansion portion 200e. The lower end portion 520b may be locked to the locking portion 200f.

The plate 560 may be disposed in the cavity 100c and fixed to the upper end of the support 520. The spring 540 may be disposed between a bottom surface of the cavity 100c and the plate 560 along the support 520. The spring 540 may bias the plate 560 upward with respect to the movable portion 100m. Accordingly, the support 520 is biased upward, and as a result, the lower end portion 520b of the support 520 is pressed against the locking portion 200f of the upper plate 200c, and the inner chamber 200 may be held and fixed to the movable portion 100m.

In an embodiment, the release mechanism 600 may include an air supply device. The air supply device may supply air to a gap between the lid body 580 and the plate 560. The release mechanism 600 may supply air to the gap between the lid body 580 and the plate 560 to press down the plate 560, so that the lower end portion 520b of the support 520 may be separated from the locking portion 200f of the upper plate 200c, and the fixation between the inner chamber 200 and the movable portion 100m may be released. In a state where the fixation of the inner chamber 200 and the movable portion 100m are released, the inner chamber 200 may be removable from the outer chamber 100.

In an embodiment, as shown in FIG. 2, the measurement device 300 may be disposed outside the outer chamber 100. The measurement device 300 may be disposed in the vicinity of the first outer transparent window 101. The measurement device 300 may be configured to optically measure the state of the inner chamber 200 via the first outer transparent window 101 and the first inner transparent window 201. The measurement device 300 may measure a consumption state and an attachment state of contaminants of the inner chamber 200 or a component thereof. The measurement device 300 may be at least one selected from the group consisting of a camera, an optical emission spectrometer (OES), and a spectrometer. The measurement device 300 may be included in a part of the plasma processing apparatus 1 or may not be included in the plasma processing apparatus 1. The measurement device 300 may be installed during use or may be installed permanently.

### <Example of Plasma Processing>

In an embodiment, the plasma processing includes etching processing of etching a film on the substrate W using plasma. In an embodiment, the plasma processing is executed by the controller 2 in the plasma processing apparatus 1.

First, the substrate W is carried into the plasma processing chamber 10 through the second opening portion 100p shown in FIG. 2, is placed on the substrate support 11, and is sucked and held on the substrate support 11.

Next, the processing gas is supplied to the shower head by the gas supply 160, and is supplied from the shower head to the plasma processing space S. The processing gas supplied at this time includes a gas that generates an active species required for the etching processing of the substrate W.

One or a plurality of RF signals are supplied from the first RF power supply 410 and the second RF power supply 420 to the upper electrode and/or the lower electrode. As a result, plasma is formed on the substrate support 11 of the plasma processing space S, and the substrate W is subjected to the etching processing.

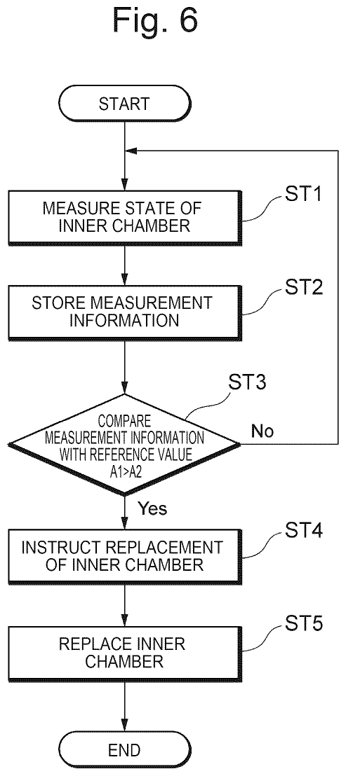

The state of the inner chamber 200 may be confirmed during the plasma processing, or after or before the plasma processing. FIG. 6 is a flowchart showing an example of processing of confirming the state of the inner chamber 200. In an embodiment, the present processing may include step ST1 of measuring the state of the inner chamber 200, step ST2 of storing measurement information, step ST3 of comparing the measurement information with a reference value, step ST4 of instructing the replacement of the inner chamber 200, and step ST5 of replacing the inner chamber 200. The present processing may be executed by the controller 2.

In an embodiment, in step ST1, the measurement device 300 shown in FIG. 2 may be operated, and the state of the inner chamber 200 may be optically measured via the first outer transparent window 101 and the first inner transparent window 201. The inner wall of the inner chamber 200 may be imaged by the camera of the measurement device 300, and the consumption state or the deposition state of impurities of the inner chamber 200 may be measured. In this way, the measurement information related to the state of the inner chamber 200 may be acquired. In addition, the state of the inner chamber 200 may be measured by measuring the state of the plasma processing space S by the measurement device 300.

In an embodiment, in step ST2, the measurement information acquired in step ST1 may be stored in the storage 2a2 of the controller 2.

In an embodiment, in step ST3, a measurement value A1 included in the measurement information and a reference value A2 set in advance may be compared. In a case where the measurement value A1 does not exceed the reference value A2, the state of the inner chamber 200 may be measured again. In a case where the measurement value A1 exceed the reference value A2, the present processing may be ended. In a case where the measurement value A1 exceeds the reference value A2, the replacement of the inner chamber 200 may be instructed in step ST4. The instruction for the replacement may be displayed on a display portion of the controller 2. Then, in step ST5, the inner chamber 200 may be replaced. The replacement may be automatically performed. In this case, the inner chamber 200 may be released from the fixation with the outer chamber 100 and carried out to the outside of the outer chamber 100 via the first opening portion 1000.

According to the present exemplary embodiment, the outer side wall 100s of the outer chamber 100 in the plasma processing apparatus 1 includes the first outer transparent window 101, the inner side wall 200s of the inner chamber 200 includes the first inner transparent window 201, and the measurement device 300 is configured to optically measure the state of the inner chamber 200 via the first outer transparent window 101 and the first inner transparent window 201. Accordingly, the state of the inner chamber 200 can be confirmed from the outside of the outer chamber 100. Since the state of the inner chamber 200 can be confirmed without opening the outer chamber 100 to the atmosphere, the processing of confirming the state of the inner chamber 200 can be performed in a short time. In addition, the state of the inner chamber 200 can be confirmed even during the plasma processing.

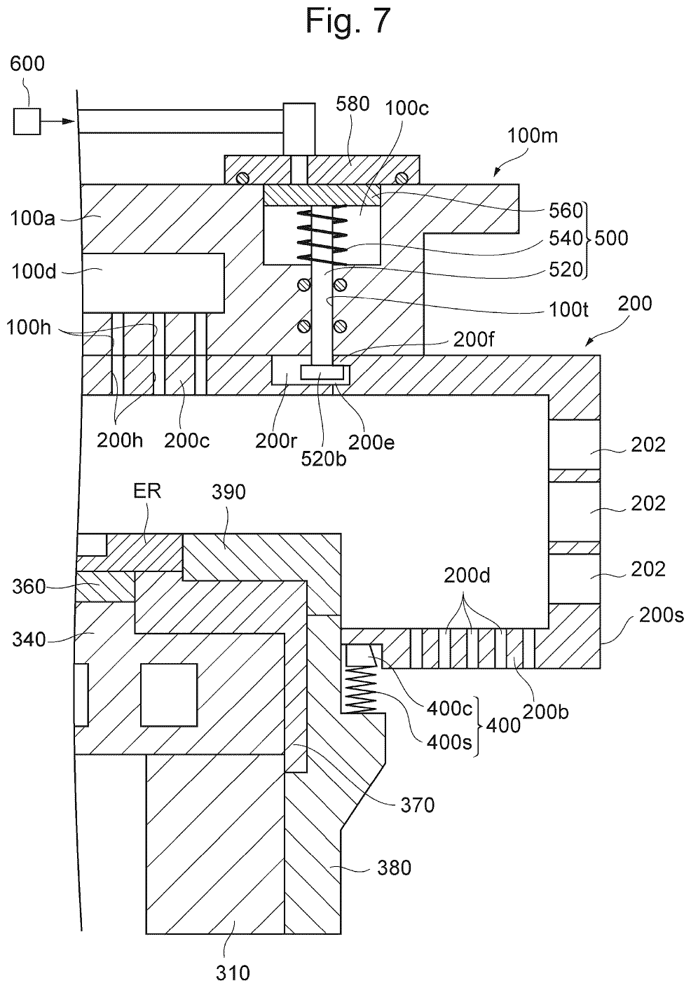

In the above-described embodiment, as shown in FIG. 7, one or a plurality of first through-holes 202 may be disposed on the inner side wall 200s instead of the first inner transparent window 201. The measurement device 300 may optically measure the state of the inner chamber 200 via the first outer transparent window 101 and the first through-hole 202.

### Second Embodiment

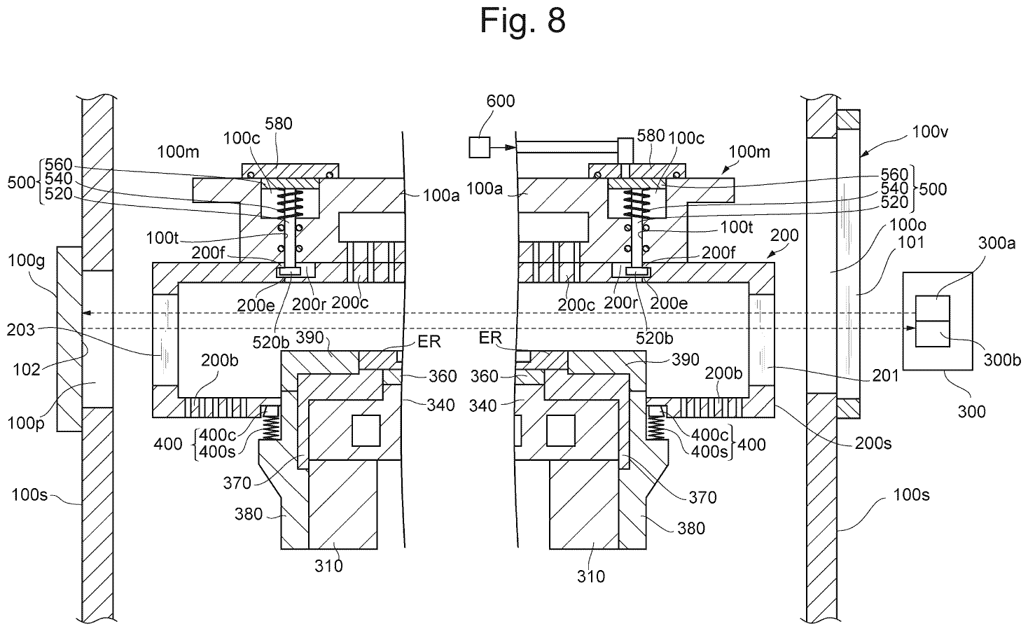

As shown in FIG. 8, the outer side wall 100s of the outer chamber 100 may include a reflection mirror 102 disposed on the opposite side of the first outer transparent window 101. The gate valve 100g that opens and closes the second opening portion 100p may include the reflection mirror 102. In addition, the inner side wall 200s of the inner chamber 200 may include a second inner transparent window 203 that faces the reflection mirror 102 and is disposed on the opposite side of the first inner transparent window 201. The second inner transparent window 203 may be made of glass, resin, or the like. The measurement device 300 may include a light source 300a disposed in the vicinity of the first outer transparent window 101 and a detector 300b disposed in the vicinity of the first outer transparent window 101. The measurement device 300 may optically measure the state of the inner chamber 200 via the first outer transparent window 101, the first inner transparent window 201, the second inner transparent window 203, and the reflection mirror 102. The light output from the light source 300a may pass through the plasma processing space S of the inner chamber 200 via the first outer transparent window 101 and the first inner transparent window 201, may be reflected by the reflection mirror 102 through the second inner transparent window 203, and may be detected by the detector 300b through the second inner transparent window 203, the first inner transparent window 201, and the first outer transparent window 101 again in this order. The configuration of the other parts of the plasma processing apparatus 1 may be the same as that of the first embodiment. The measurement device 300 may measure the consumption state or the deposition state of impurities of the inner chamber 200 by allowing light to pass through the plasma processing space S in the inner chamber 200 and detecting the light. The measurement device 300 may measure the consumption state or the deposition state of impurities of the inner chamber 200 by reflecting light on the inner wall of the inner chamber 200 and detecting the light.

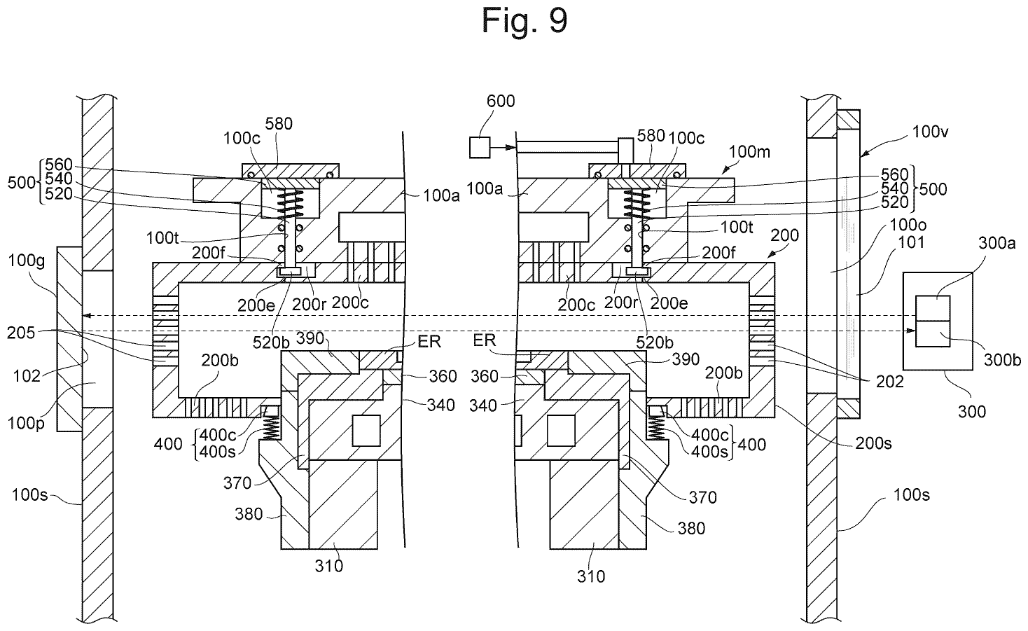

In the present embodiment, as shown in FIG. 9, one or a plurality of first through-holes 202 may be disposed on the inner side wall 200s of the inner chamber 200 instead of the first inner transparent window 201. In addition, one or a plurality of second through-holes 205 may be disposed on the inner side wall 200s of the inner chamber 200 instead of the second inner transparent window 203. In this case, the measurement device 300 may optically measure the state of the inner chamber 200 via the first outer transparent window 101, the first through-hole 202, the second through-hole 205, and the reflection mirror 102. The light output from the light source 300a may pass through the plasma processing space S of the inner chamber 200 via the first outer transparent window 101 and the first through-hole 202, may be reflected by the reflection mirror 102 through the second through-hole 205, and may be detected by the detector 300b through the second through-hole 205, the first through-hole 202, and the first outer transparent window 101 again in this order.

### Third Embodiment

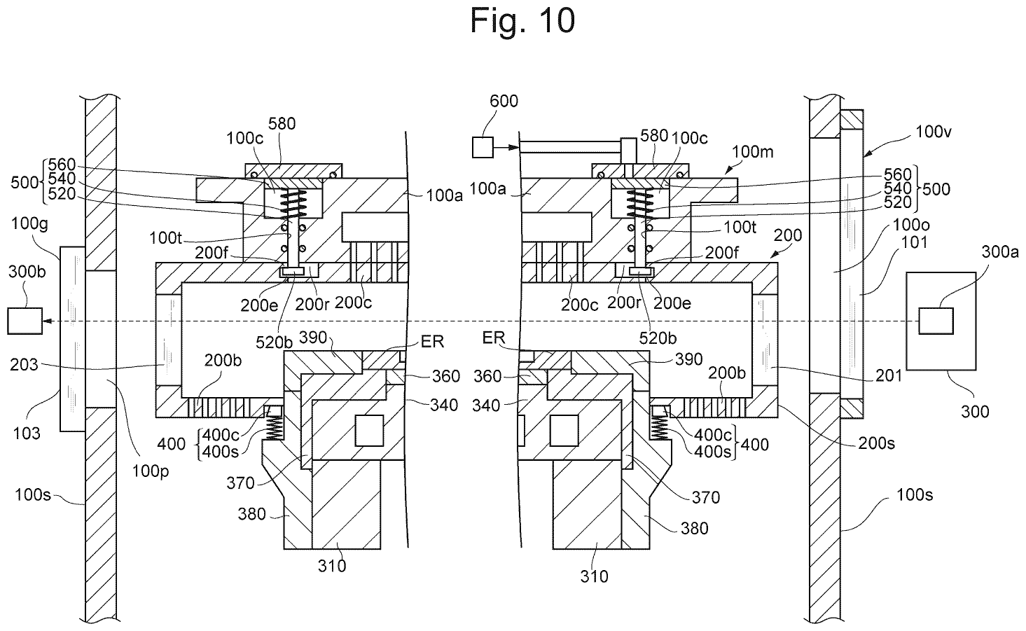

As shown in FIG. 10, the outer side wall 100s of the outer chamber 100 may include a second outer transparent window 103 disposed on the opposite side of the first outer transparent window 101. The gate valve 100g that opens and closes the second opening portion 100p may include the second outer transparent window 103. The second outer transparent window 103 may be made of glass, resin, or the like. In addition, the inner side wall 200s of the inner chamber 200 may include the second inner transparent window 203 that faces the second outer transparent window 103 and is disposed on the opposite side of the first inner transparent window 201. The measurement device 300 may include the light source 300a disposed in the vicinity of the first outer transparent window 101 and the detector 300b disposed in the vicinity of the second outer transparent window 103. The measurement device 300 may optically measure the state of the inner chamber 200 via the first outer transparent window 101, the first inner transparent window 201, the second inner transparent window 203, and the second outer transparent window 103. The light output from the light source 300a may pass through the plasma processing space S of the inner chamber 200 via the first outer transparent window 101 and the first inner transparent window 201, and may be detected by the detector 300b via the second inner transparent window 203 and the second outer transparent window 103. The configuration of the other parts of the plasma processing apparatus 1 may be the same as that of the first embodiment.

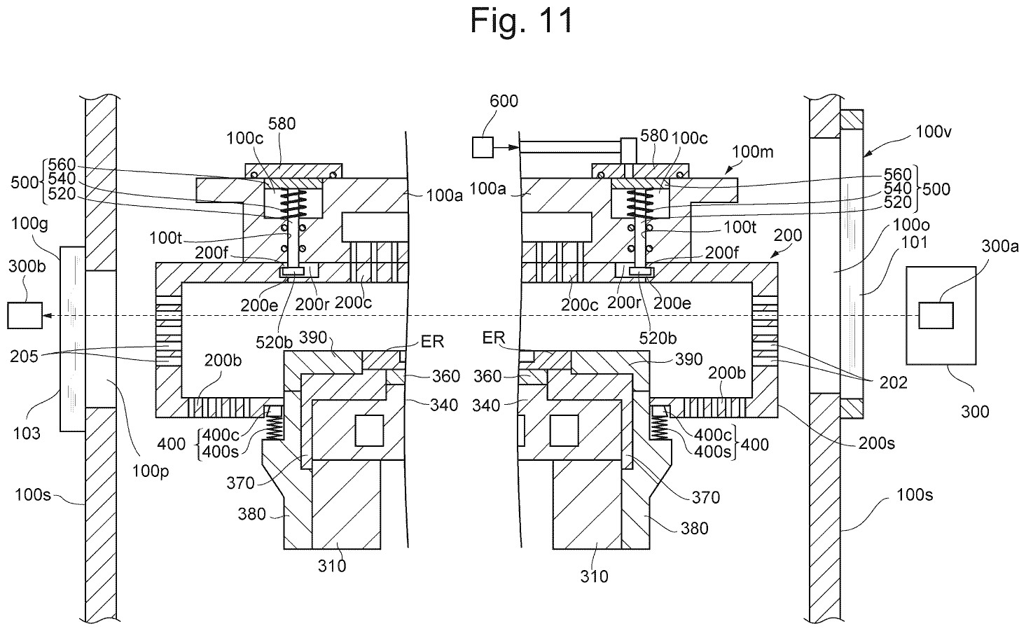

In the present embodiment, as shown in FIG. 11, one or the plurality of first through-holes 202 may be disposed on the inner side wall 200s of the inner chamber 200 instead of the first inner transparent window 201. In addition, one or a plurality of second through-holes 205 may be disposed on the inner side wall 200s of the inner chamber 200 instead of the second inner transparent window 203. In this case, the measurement device 300 may optically measure the state of the inner chamber 200 via the first outer transparent window 101, the first through-hole 202, the second through-hole 205, and the second outer transparent window 103. The light output from the light source 300a may pass through the plasma processing space S of the inner chamber 200 via the first outer transparent window 101 and the first through-hole 202, and may be detected by the detector 300b via the second through-hole 205 and the second outer transparent window 103.

In the above-described embodiment, a plurality of measurement devices 300 may be used. As shown in FIG. 5, a plurality of (two in FIG. 5) first outer transparent windows 101 may be disposed. In addition, a plurality of the first inner transparent windows 201, a plurality of the second outer transparent windows 103, and a plurality of the second inner transparent windows 203 may be disposed, respectively. In this case, at least one transparent window may be used to allow passing of light output from the light source 300a, and at least one transparent window may be used to allow passing of light detected by the detector 300b. In addition, in a case where the plurality of measurement devices are used, a plurality of transparent windows may be used to allow passing of light of different measurement devices, respectively.

The embodiments of the present disclosure further include the following aspects.

### (Addendum 1)

A plasma processing apparatus including:
an outer chamber including an outer side wall, the outer side wall defining at least an inner space, and the outer side wall including a first outer transparent window;
a substrate support disposed in the inner space of the outer chamber and having a substrate support surface;
a replaceable inner chamber disposed in the inner space of the outer chamber, in which
the replaceable inner chamber includes
   an upper plate extending in a horizontal direction above the substrate support,
   an annular bottom plate extending outward from a side wall of the substrate support, and
   an inner side wall extending in a vertical direction to connect an outer periphery of the upper plate to an outer periphery of the annular bottom plate,
a plasma processing space is defined by the substrate support, the upper plate, the annular bottom plate, and the inner side wall, and
the inner side wall includes a first inner transparent window disposed to face the first outer transparent window; and
a measurement device configured to optically measure a state of the replaceable inner chamber via the first outer transparent window and the first inner transparent window.

### (Addendum 2)

The plasma processing apparatus according to Addendum 1, in which
the outer side wall has an opening portion,
the outer chamber includes a gate valve configured to open and close the opening portion, and
the gate valve includes the first outer transparent window.

### (Addendum 3)

The plasma processing apparatus according to Addendum 1, in which
the outer side wall includes a reflection mirror disposed on an opposite side of the first outer transparent window,
the inner side wall includes a second inner transparent window, and the second inner transparent window facing the reflection mirror and disposed on an opposite side of the first inner transparent window,
the measurement device includes
   a light source disposed in a vicinity of the first outer transparent window, and
   a detector disposed in the vicinity of the first outer transparent window, and
the measurement device is configured to optically measure the state of the replaceable inner chamber via the first outer transparent window, the first inner transparent window, the second inner transparent window, and the reflection mirror.

### (Addendum 4)

The plasma processing apparatus according to Addendum 3, in which
the outer side wall has a first opening portion and a second opening portion, and the second opening portion located on an opposite side of the first opening portion,
the outer chamber includes
   a first gate valve configured to open and close the first opening portion, and
   a second gate valve configured to open and close the second opening portion,
the first gate valve includes the first outer transparent window, and
the second gate valve includes the reflection mirror.

### (Addendum 5)

The plasma processing apparatus according to Addendum 1, in which
the outer side wall includes a second outer transparent window disposed on an opposite side of the first outer transparent window,
the inner side wall includes a second inner transparent window, and the second inner transparent window facing the second outer transparent window and disposed on an opposite side of the first inner transparent window,
the measurement device includes
   a light source disposed in a vicinity of the first outer transparent window, and
   a detector disposed in a vicinity of the second outer transparent window, and
the measurement device is configured to optically measure the state of the replaceable inner chamber via the first outer transparent window, the first inner transparent window, the second inner transparent window, and the second outer transparent window.

### (Addendum 6)

The plasma processing apparatus according to Addendum 5, in which
the outer side wall has a first opening portion and a second opening portion, and the second opening portion located on an opposite side of the first opening portion,
the outer chamber includes
   a first gate valve configured to open and close the first opening portion, and
   a second gate valve configured to open and close the second opening portion,
the first gate valve includes the first outer transparent window, and
the second gate valve includes the second outer transparent window.

### (Addendum 7)

A plasma processing apparatus including:
an outer chamber including an outer side wall, the outer side wall defining at least an inner space, and the outer side wall including a first outer transparent window;
a substrate support disposed in the inner space of the outer chamber and having a substrate support surface;
a replaceable inner chamber disposed in the inner space of the outer chamber, in which
the replaceable inner chamber includes
   an upper plate extending in a horizontal direction above the substrate support,
   an annular bottom plate extending outward from a side wall of the substrate support, and
   an inner side wall extending in a vertical direction to connect an outer periphery of the upper plate to an outer periphery of the annular bottom plate,
a plasma processing space is defined by the substrate support, the upper plate, the annular bottom plate, and the inner side wall, and
the inner side wall includes at least one first through-hole facing the first outer transparent window; and
a measurement device configured to optically measure a state of the replaceable inner chamber via the first outer transparent window and the at least one first through-hole.

### (Addendum 8)

The plasma processing apparatus according to Addendum 7, in which
the outer side wall has an opening portion,
the outer chamber includes a gate valve configured to open and close the opening portion, and
the gate valve includes the first outer transparent window.

### (Addendum 9)

The plasma processing apparatus according to Addendum 7, in which
the outer side wall includes a reflection mirror disposed on an opposite side of the first outer transparent window,
the inner side wall includes at least one second through-hole, and the at least one first through-hole facing the reflection mirror and located on an opposite side of the at least one first through-hole,
the measurement device includes
   a light source disposed in a vicinity of the first outer transparent window, and
   a detector disposed in the vicinity of the first outer transparent window, and
the measurement device is configured to optically measure the state of the replaceable inner chamber via the first outer transparent window, the at least one first through-hole, the at least one second through-hole, and the reflection mirror.

### (Addendum 10)

The plasma processing apparatus according to Addendum 9, in which
the outer side wall has a first opening portion and a second opening portion, and the second opening portion located on an opposite side of the first opening portion,
the outer chamber includes
   a first gate valve configured to open and close the first opening portion, and
   a second gate valve configured to open and close the second opening portion,
the first gate valve includes the first outer transparent window, and
the second gate valve includes the reflection mirror.

### (Addendum 11)

The plasma processing apparatus according to Addendum 7, in which
the outer side wall includes a second outer transparent window disposed on an opposite side of the first outer transparent window,
the inner side wall has at least one second through-hole, and the at least one second through-hole facing the second outer transparent window and located on an opposite side of the at least one first through-hole,
the measurement device includes
   a light source disposed in a vicinity of the first outer transparent window, and
   a detector disposed in a vicinity of the second outer transparent window, and
the measurement device is configured to optically measure the state of the replaceable inner chamber via the first outer transparent window, the at least one first through-hole, the at least one second through-hole, and the second outer transparent window.

### (Addendum 12)

The plasma processing apparatus according to Addendum 11, in which
the outer side wall has a first opening portion and a second opening portion, and the second opening portion located on an opposite side of the first opening portion,
the outer chamber includes
   a first gate valve configured to open and close the first opening portion, and
   a second gate valve configured to open and close the second opening portion,
the first gate valve includes the first outer transparent window, and
the second gate valve includes the second outer transparent window.

### (Addendum 13)

A plasma processing apparatus including:
an outer chamber including an outer side wall, the outer side wall defining at least an inner space, and the outer side wall including a first outer transparent window;
a substrate support disposed in the inner space of the outer chamber and having a substrate support surface; and
a replaceable inner chamber disposed in the inner space of the outer chamber, in which
the replaceable inner chamber includes
   an upper plate extending in a horizontal direction above the substrate support,
   an annular bottom plate extending outward from a side wall of the substrate support, and
   an inner side wall extending in a vertical direction to connect an outer periphery of the upper plate to an outer periphery of the annular bottom plate,
a plasma processing space is defined by the substrate support, the upper plate, the annular bottom plate, and the inner side wall, and
the inner side wall includes a first inner transparent window disposed to face the first outer transparent window.

### (Addendum 14)

The plasma processing apparatus according to Addendum 13, in which
the outer side wall has an opening portion,
the outer chamber includes a gate valve configured to open and close the opening portion, and
the gate valve includes the first outer transparent window.

### (Addendum 15)

The plasma processing apparatus according to Addendum 13 or 14, in which
the outer side wall includes a reflection mirror disposed on an opposite side of the first outer transparent window, and
the inner side wall includes a second inner transparent window, and the second inner transparent window facing the reflection mirror and disposed on an opposite side of the first inner transparent window.

### (Addendum 16)

The plasma processing apparatus according to Addendum 13 or 14, in which
the outer side wall includes a second outer transparent window disposed on an opposite side of the first outer transparent window,
the inner side wall includes a second inner transparent window, and the second inner transparent window facing the second outer transparent window and disposed on an opposite side of the first inner transparent window.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to another embodiment. In addition, some configuration elements in one embodiment are able to be replaced with corresponding configuration elements in another embodiment.

According to one exemplary embodiment of the present disclosure, it is possible to provide a technique that is able to confirm the state of the inner chamber from the outside in the plasma processing apparatus.

What is claimed is:

1. A plasma processing apparatus comprising:
an outer chamber including an outer side wall, the outer side wall defining at least an inner space, and the outer side wall including a first outer transparent window;
a substrate support disposed in the inner space of the outer chamber and having a substrate support surface;
a replaceable inner chamber disposed in the inner space of the outer chamber, in which the replaceable inner chamber includes:
an upper plate extending in a horizontal direction above the substrate support;
an annular bottom plate extending outward from a side wall of the substrate support; and
an inner side wall extending in a vertical direction to connect an outer periphery of the upper plate to an outer periphery of the annular bottom plate;
a plasma processing space is defined by the substrate support, the upper plate, the annular bottom plate, and the inner side wall,
wherein the inner side wall includes a first inner transparent window disposed to face the first outer transparent window; and
a measurement device configured to optically measure a state of the replaceable inner chamber via the first outer transparent window and the first inner transparent window.

2. The plasma processing apparatus according to claim 1, wherein
the outer side wall has an opening portion,
the outer chamber includes a gate valve configured to open and close the opening portion, and
the gate valve includes the first outer transparent window.

3. The plasma processing apparatus according to claim 1, wherein
the outer side wall includes a reflection mirror disposed on an opposite side of the first outer transparent window,
the inner side wall includes a second inner transparent window, and the second inner transparent window facing the reflection mirror and disposed on an opposite side of the first inner transparent window,
the measurement device includes;
a light source disposed in a vicinity of the first outer transparent window; and
a detector disposed in the vicinity of the first outer transparent window; and
the measurement device is configured to optically measure the state of the replaceable inner chamber via the first outer transparent window, the first inner transparent window, the second inner transparent window, and the reflection mirror.

4. The plasma processing apparatus according to claim 3, wherein
the outer side wall has a first opening portion and a second opening portion, and the second opening portion located on an opposite side of the first opening portion,
the outer chamber includes:
a first gate valve configured to open and close the first opening portion; and
a second gate valve configured to open and close the second opening portion;
the first gate valve includes the first outer transparent window; and
the second gate valve includes the reflection mirror.

5. The plasma processing apparatus according to claim 1, wherein
the outer side wall includes a second outer transparent window disposed on an opposite side of the first outer transparent window,
the inner side wall includes a second inner transparent window, and the second inner transparent window facing the second outer transparent window and disposed on an opposite side of the first inner transparent window,
the measurement device includes:
a light source disposed in a vicinity of the first outer transparent window; and
a detector disposed in a vicinity of the second outer transparent window; and
the measurement device is configured to optically measure the state of the replaceable inner chamber via the first outer transparent window, the first inner transparent window, the second inner transparent window, and the second outer transparent window.

6. The plasma processing apparatus according to claim 5, wherein
the outer side wall has a first opening portion and a second opening portion, and the second opening portion located on an opposite side of the first opening portion,
the outer chamber includes:
a first gate valve configured to open and close the first opening portion; and
a second gate valve configured to open and close the second opening portion,
the first gate valve includes the first outer transparent window, and
the second gate valve includes the second outer transparent window.

7. A plasma processing apparatus comprising:
an outer chamber including an outer side wall, the outer side wall defining at least an inner space, and the outer side wall including a first outer transparent window;
a substrate support disposed in the inner space of the outer chamber and having a substrate support surface;
a replaceable inner chamber disposed in the inner space of the outer chamber, in which the replaceable inner chamber includes:
an upper plate extending in a horizontal direction above the substrate support;
an annular bottom plate extending outward from a side wall of the substrate support; and
an inner side wall extending in a vertical direction to connect an outer periphery of the upper plate to an outer periphery of the annular bottom plate,
a plasma processing space is defined by the substrate support, the upper plate, the annular bottom plate, and the inner side wall,
wherein the inner side wall includes at least one first through-hole facing the first outer transparent window; and
a measurement device configured to optically measure a state of the replaceable inner chamber via the first outer transparent window and the at least one first through-hole.

8. The plasma processing apparatus according to claim 7, wherein
the outer side wall has an opening portion,
the outer chamber includes a gate valve configured to open and close the opening portion, and
the gate valve includes the first outer transparent window.

9. The plasma processing apparatus according to claim 7, wherein
the outer side wall includes a reflection mirror disposed on an opposite side of the first outer transparent window,
the inner side wall includes at least one second through-hole, and the at least one first through-hole facing the reflection mirror and located on an opposite side of the at least one first through-hole,
the measurement device includes:
a light source disposed in a vicinity of the first outer transparent window; and
a detector disposed in the vicinity of the first outer transparent window; and
the measurement device is configured to optically measure the state of the replaceable inner chamber via the first outer transparent window, the at least one first through-hole, the at least one second through-hole, and the reflection mirror.

10. The plasma processing apparatus according to claim 9, wherein
the outer side wall has a first opening portion and a second opening portion, and the second opening portion located on an opposite side of the first opening portion,
the outer chamber includes:
a first gate valve configured to open and close the first opening portion; and
a second gate valve configured to open and close the second opening portion,
the first gate valve includes the first outer transparent window, and
the second gate valve includes the reflection mirror.

11. The plasma processing apparatus according to claim 7, wherein
the outer side wall includes a second outer transparent window disposed on an opposite side of the first outer transparent window,
the inner side wall has at least one second through-hole, and the at least one second through-hole facing the second outer transparent window and located on an opposite side of the at least one first through-hole,
the measurement device includes:
a light source disposed in a vicinity of the first outer transparent window; and
a detector disposed in a vicinity of the second outer transparent window, and
the measurement device is configured to optically measure the state of the replaceable inner chamber via the first outer transparent window, the at least one first through-hole, the at least one second through-hole, and the second outer transparent window.

12. The plasma processing apparatus according to claim 11, wherein
the outer side wall has a first opening portion and a second opening portion, and the second opening portion located on an opposite side of the first opening portion,
the outer chamber includes:
a first gate valve configured to open and close the first opening portion; and
a second gate valve configured to open and close the second opening portion,
the first gate valve includes the first outer transparent window, and
the second gate valve includes the second outer transparent window.

13. A plasma processing apparatus comprising:
an outer chamber including an outer side wall, the outer side wall defining at least an inner space, and the outer side wall including a first outer transparent window;
a substrate support disposed in the inner space of the outer chamber and having a substrate support surface; and
a replaceable inner chamber disposed in the inner space of the outer chamber, in which
the replaceable inner chamber includes:
an upper plate extending in a horizontal direction above the substrate support;
an annular bottom plate extending outward from a side wall of the substrate support; and
an inner side wall extending in a vertical direction to connect an outer periphery of the upper plate to an outer periphery of the annular bottom plate; and
a plasma processing space is defined by the substrate support, the upper plate, the annular bottom plate, and the inner side wall,
wherein the inner side wall includes a first inner transparent window disposed to face the first outer transparent window.

14. The plasma processing apparatus according to claim 13, wherein
the outer side wall has an opening portion,
the outer chamber includes a gate valve configured to open and close the opening portion, and
the gate valve includes the first outer transparent window.

15. The plasma processing apparatus according to claim 13, wherein
the outer side wall includes a reflection mirror disposed on an opposite side of the first outer transparent window, and
the inner side wall includes a second inner transparent window, and the second inner transparent window facing the reflection mirror and disposed on an opposite side of the first inner transparent window.

16. The plasma processing apparatus according to claim 13, wherein
the outer side wall includes a second outer transparent window disposed on an opposite side of the first outer transparent window,
the inner side wall includes a second inner transparent window, and the second inner transparent window facing the second outer transparent window and disposed on an opposite side of the first inner transparent window.
